(19) United States
(12) Patent Application Publication
(10) Pub. No.: US 2025/0077181 A1
(43) Pub. Date: Mar. 6, 2025

(54) IN-MEMORY ATTENTION ENGINE

(71) Applicant: Hewlett Packard Enterprise Development LP, Spring, TX (US)

(72) Inventors: Giacomo Pedretti, San Francisco, CA (US); James S. Ignowski, Ft. Collins, CO (US)

(21) Appl. No.: 18/460,322

(22) Filed: Sep. 1, 2023

(51) Int. Cl. G06F 7/544; G06F 7/523; H03M 1/12; H03M 1/66

(52) U.S. Cl. CPC G06F 7/5443; G06F 7/523; H03M 1/12; H03M 1/66

(57) ABSTRACT

A computing system that includes an attention engine is disclosed. The attention engine is an in-memory computing module that may be used to accelerate attention operations. The attention engine includes a dot product circuit and a multiplier circuit, which together are used to perform matrix generation and matrix multiplication in the analog domain. Performing matrix multiplication in the analog domain may be faster and/or consume less power than performing matrix multiplication in the digital domain.

### BACKGROUND

Neural networks are a class of machine learning algorithms inspired by the structure and function of the human brain. They consist of interconnected nodes, organized into layers, where each node takes input data, processes it, and passes the output to the next layer. These networks are trained on vast amounts of data, by adjusting the connection strengths (e.g., weights) between nodes. As a result, neural networks can learn complex patterns and representations from the data, enabling them to excel in tasks like natural language processing, image recognition, and decision-making. A significant advancement in neural networks is the transformer architecture.

### BRIEF DESCRIPTION OF THE DRAWINGS

Aspects of the present disclosure are best understood from the following detailed description when read with the accompanying figures.

FIG. 1 is a block diagram of a computing system, according to some implementations.

FIG. 2 is a block diagram of some components of an attention engine, according to some implementations.

FIG. 3 is a schematic diagram of an attention engine, according to some implementations.

FIG. 4 is a diagram of a programmable crossbar array for an attention engine, according to some implementations.

FIG. 5 is a block diagram of some components of an attention engine, according to some implementations.

FIG. 6 is a diagram of an attention engine programming method, according to some implementations.

FIG. 7 is a diagram of a transformation method, according to some implementations.

Corresponding numerals and symbols in the different figures generally refer to corresponding parts unless otherwise indicated. The figures are drawn to clearly illustrate the relevant aspects of the disclosure and are not necessarily drawn to scale.

### DETAILED DESCRIPTION

The following disclosure provides many different examples for implementing different features. Specific examples of components and arrangements are described below to simplify the present disclosure. These are, of course, merely examples and are not intended to be limiting.

One type of neural network is a large language model (LLM). An LLM may be trained to predict a token for a segment. The predicted token may be the next token for the segment or may be a missing token for the segment. Some types of LLMs, such as generative pre-trained transformers (GPTs), use a transformer architecture. In a transformer architecture, an LLM is organized into multiple layers, with each layer including a transformer. A transformer obtains an input sequence, adds information to help clarify the meaning of elements in the input sequence, and generates an output sequence (also called a hidden state sequence). The hidden state sequence generated by a transformer is fed into a corresponding subsequent transformer. The hidden state sequence generated by the final layer is used to predict the token for the segment.

The transformer architecture uses an attention mechanism. Each transformer performs an attention operation. An attention operation calculates the relationships of the elements of a sequence to one another. A transformer uses an attention operation to add information to its input sequence when generating its hidden state sequence. One attention mechanism that may be used in a transformer architecture is Scaled Dot-Product Attention (SDPA). The performance of a neural network that uses SDPA depends on the length of the input sequence. For longer input sequence lengths, SDPA operations may dominate the processing time for the neural network. Thus, increasing the speed of SDPA operations may decrease the neural network's processing time.

In an example implementation, the present disclosure discloses a computing system that includes an attention engine. The attention engine is an in-memory computing module that may be used to accelerate SDPA operations for the computing system. The attention engine includes a dot product circuit and a multiplier circuit, which collectively are used to perform matrix multiplication for SDPA operations.

In an example implementation, the dot product circuit includes dot product engines (DPEs), which are part of programmable crossbar arrays, and are used to generate matrices for an attention operation. The multiplier circuit is coupled to the dot product engines, and can be used to multiply the matrices generated by the dot product engines. The matrix generation and matrix multiplication can both be performed in the analog domain.

In an example implementation, digital inputs to the attention engine can be converted to analog input signals. The analog input signals are input to the dot product circuit, which, together with the multiplier circuit, perform matrix generation and multiplication in the analog domain and produce analog output signals. The analog output signals are then converted back to digital outputs from the attention engine. Performing matrix multiplication in the analog domain may be faster and/or consume less power than performing matrix multiplication in the digital domain. Accordingly, the performance of SDPA operations may be improved.

In an example implementation, the inputs for an SDPA operation include queries, keys, and values. The queries, keys, and values are generated from an input sequence for a transformer. The output of SDPA may be calculated according to Equations (1)-(4).

$$A = SoftMax ( \frac{{QK}^{T}}{\sqrt{{d}_{k}}} ) V \qquad ( 1 )$$

$$Q = {XW}^{Q} \qquad ( 2 )$$

$$K = {XW}^{K} \qquad ( 3 )$$

$$V = {XW}^{V} \qquad ( 4 )$$

In Equations (1)-(4), X is an input matrix. Each element of the input sequence is a vector, and each row of the input matrix X is an element of an input sequence. Additionally, dₖ is the length of each element of the input sequence, W^{Q} is a query weight matrix, W^{K} is a key weight matrix, and WY is a value weight matrix. The query matrix Q is calculated by multiplying X and W^{Q}. The key matrix K is calculated by multiplying X and W^{K}. The value matrix V is calculated by multiplying X and W^{V}. Finally, A is the resulting attention matrix. The attention engine of the present disclosure may be used to perform at least some of the matrix multiplication operations in Equations (1)-(4), and does so in the analog domain instead of in the digital domain. The speed of an SDPA operation may thus be increased.

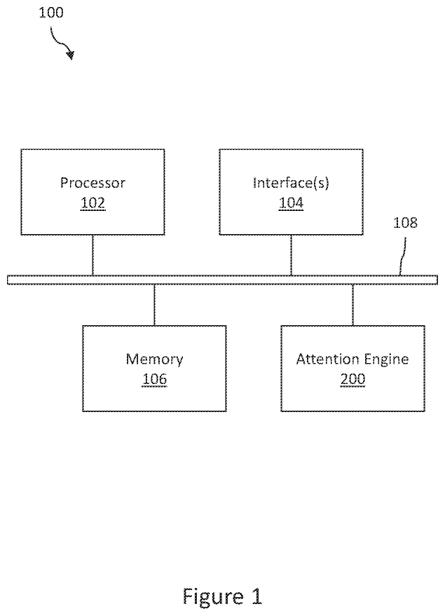

FIG. 1 is a block diagram of an example computing system 100, that can be used to operate an LLM based on the transformer architecture as previously described. The computing system 100 may be implemented in an electronic device. Examples of electronic devices include servers, desktop computers, laptop computers, mobile devices, gaming systems, and the like.

The computing system 100 may be utilized in any data processing scenario, including stand-alone hardware, mobile applications, or combinations thereof. Further, the computing system 100 may be used in a computing network, such as a public cloud network, a private cloud network, a hybrid cloud network, other forms of networks, or combinations thereof. In one example, the methods provided by the computing system 100 are provided as a service over a network by, for example, a third party. The computing system 100 may be implemented on one or more hardware platforms, in which the modules in the system can be executed on one or more platforms. Such modules can run on various forms of cloud technologies and hybrid cloud technologies or be offered as a Software-as-a-Service that can be implemented on or off a cloud.

To achieve its desired functionality, the computing system 100 includes various hardware components. These hardware components may include a processor 102, one or more interface(s) 104, a memory 106, and an attention engine 200. The hardware components may be interconnected through a number of busses and/or network connections. In one example, the processor 102, the interface(s) 104, the memory 106, and the attention engine 200 may be communicatively coupled via a bus 108.

The processor 102 retrieves executable code from the memory 106 and executes the executable code. The executable code may, when executed by the processor 102, cause the processor 102 to implement any functionality described herein. The processor 102 may be a microprocessor, an application-specific integrated circuit, a microcontroller, or the like.

The interface(s) 104 enable the processor 102 to interface with various other hardware elements, external and internal to the computing system 100. For example, the interface(s) 104 may include interface(s) to input/output devices, such as, for example, a display device, a mouse, a keyboard, etc. Additionally or alternatively, the interface(s) 104 may include interface(s) to an external storage device, or to a number of network devices, such as servers, switches, and routers, client devices, other types of computing devices, and combinations thereof.

The memory 106 may include various types of memory modules, including volatile and nonvolatile memory. For example, the memory 106 may include Random Access Memory (RAM), Read Only Memory (ROM), a Hard Disk Drive (HDD), or the like. The memory 106 may include a non-transitory computer readable medium that stores instructions for execution by the processor 102. One or more modules within the computing system 100 may be partially or wholly embodied as software and/or hardware for performing any functionality described herein. Different types of memory may be used for different data storage needs. For example, in certain examples the processor 102 may boot from ROM, maintain nonvolatile storage in an HDD, and execute program code stored in RAM.

The attention engine 200 is an accelerator for performing an attention operation, which is separate from the processor 102 and from the memory 106. The attention engine 200 may be an in-memory computing module that may be used to accelerate SDPA operations. The attention engine 200 includes one or more dot product circuit(s) and one or more multiplier circuit(s) that are collectively configured to perform an SDPA operation in the analog domain. The dot product circuit(s) each include a plurality of dot product engines. A dot product engine is implemented with a programmable crossbar array used to perform a matrix multiplication. A programmable crossbar array includes a number of programmable non-volatile analog elements that function together within an array to perform a weighted sum of multiple inputs. The programmable crossbar array may be used as an accelerator in which the array performs a number of functions faster than software running on a more general-purpose processing device.

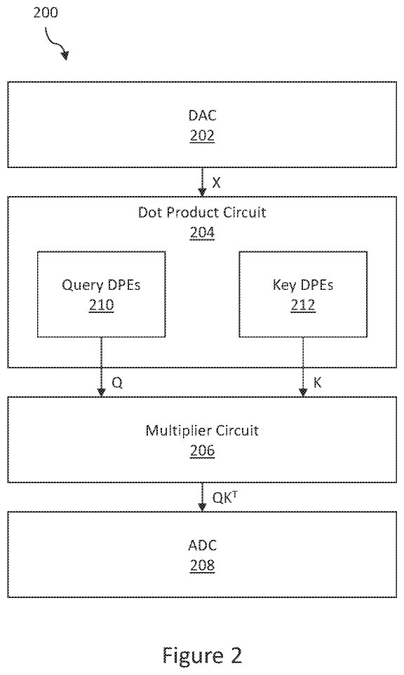

FIG. 2 is a block diagram of some components of an attention engine 200, according to some implementations. The attention engine 200 is used to perform matrix generation and multiplication operations. Specifically, the attention engine 200 may be used to generate a query matrix Q and a key matrix K using Equations (2) and (3), respectively, and then calculate QK^{T} in Equation (1) by multiplying the query matrix Q with a transpose of the key matrix K. The attention engine 200 may include a digital-to-analog converter 202, a dot product circuit 204, a multiplier circuit 206, and an analog-to-digital converter 208. FIG. 2 illustrates a flow of signals in the attention engine 200, wherein signals in the analog domain are shown with solid lines.

The digital-to-analog converter 202 receives a digital input matrix X from the processor 102 (see FIG. 1) and converts the digital input matrix X to an analog input matrix X. Each row of the digital input matrix X is an element of an input sequence for a transformer. Each element of the analog input matrix X is an analog signal that corresponds to an element of the digital input matrix X for the transformer. Specifically, the voltage of an element of the analog input matrix X may be proportional to the digital value of the corresponding element of the digital input matrix X. Example digital-to-analog converters include resistor strings, delta-sigma modulators, and the like. The digital-to-analog converter 202 may include a plurality of converter modules (e.g., one for each row of the digital input matrix X), or one converter module with multiple channels.

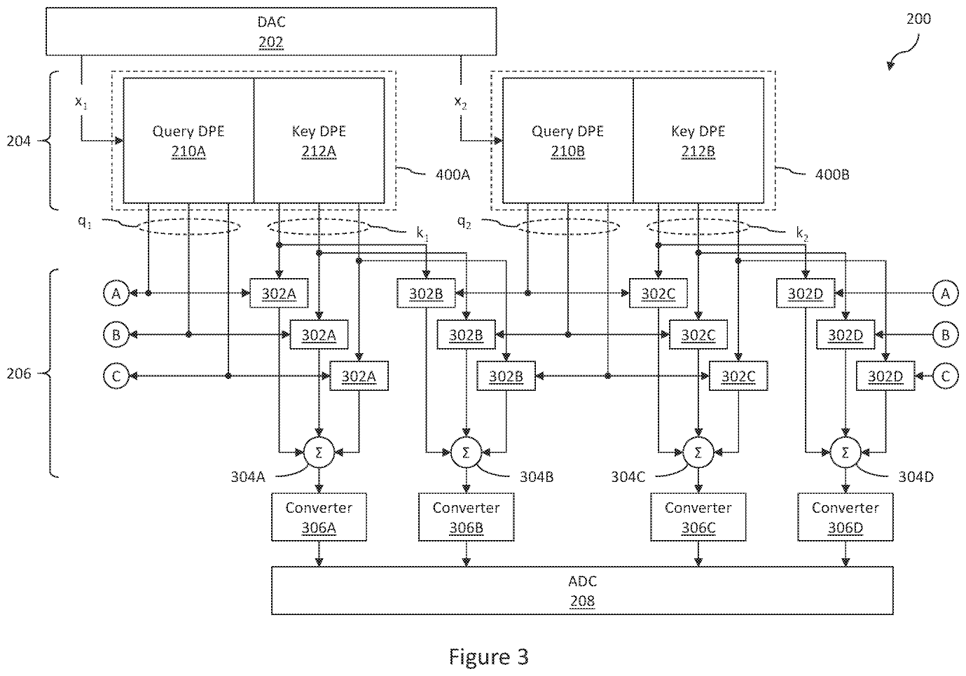

The dot product circuit 204 is coupled to the digital-to-analog converter 202. The dot product circuit 204 receives the analog input matrix X from the digital-to-analog converter 202 and generates an analog query matrix Q and an analog key matrix K. Each element of the analog query matrix Q is an analog signal that corresponds to an element of a digital query matrix Q (see Equation (2)). Each element of the analog key matrix K is an analog signal that corresponds to an element of a digital key matrix K (see Equation (3)). The dot product circuit 204 may include query dot product engines 210 and key dot product engines 212. An example implementation of the dot product circuit 204 will be subsequently described for FIG. 3.

Each of the query dot product engines 210 store values corresponding to a query weight matrix W^{Q} (see Equation (2)). Specifically, each of the query dot product engines 210 is part of a different programmable crossbar array that stores the values corresponding to the query weight matrix W^{Q}. The query dot product engines 210 are configured to generate the analog query matrix Q by multiplying the analog input matrix X with the query weight matrix W^{Q} stored in the query dot product engines 210.

Each of the key dot product engines 212 store values corresponding to a key weight matrix W^{K} (see Equation (3)). Specifically, each of the key dot product engines 212 is part of a different programmable crossbar array that stores the values corresponding to the key weight matrix W^{K}. The key dot product engines 212 are configured to generate the analog key matrix K by multiplying the analog input matrix X with the key weight matrix W^{K} stored in the key dot product engines 212.

The multiplier circuit 206 is coupled to the dot product circuit 204. The multiplier circuit 206 is configured to calculate an analog output matrix QK^{T} by multiplying the analog query matrix Q with the transpose of the analog key matrix K. Each element of the analog output matrix QK^{T} is an analog signal that corresponds to an element of a matrix that would result if the digital query matrix Q were multiplied with the transpose the digital key matrix K in the digital domain. Thus, the multiplier circuit 206 performs, in the analog domain, an equivalent of a matrix multiplication in the digital domain. An example implementation of the multiplier circuit 206 will be subsequently described for FIG. 3.

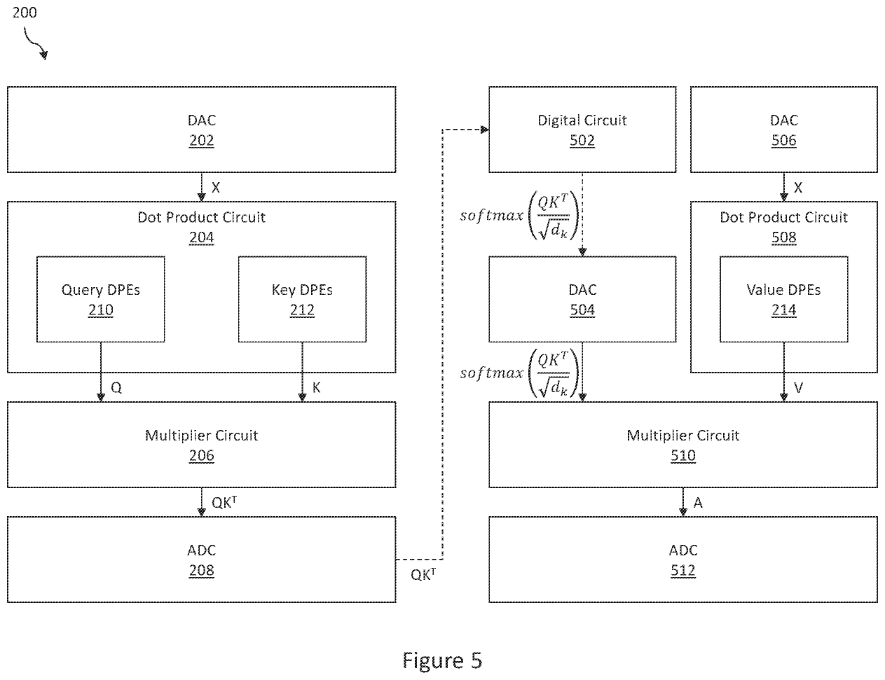

The analog-to-digital converter 208 is coupled to the multiplier circuit 206. The analog-to-digital converter 208 receives the analog output matrix QK^{T} and converts the analog output matrix QK^{T} to a digital output matrix QK^{T}. Each element of the digital output matrix QK^{T} is the result of taking the dot product of a row of the digital query matrix Q and a corresponding row of the digital key matrix K. The digital output matrix QK^{T} may be output to the processor 102 (see FIG. 1) or may be output to a digital circuit (subsequently discussed for FIG. 5). Other appropriate operations from Equation (1) may then be performed with the digital output matrix QK^{T} to compute the output sequence for the transformer. Example analog-to-digital converters include successive-approximation converters, sigma-delta modulators, and the like.

FIG. 3 is a schematic diagram of an attention engine 200, according to some implementations. An example implementation of the dot product circuit 204 and the multiplier circuit 206 are shown, but they may be implemented other ways. The attention engine 200 accepts a digital input matrix X. Each row of the digital input matrix X is an element of an input sequence for a transformer. The attention engine 200 includes one query dot product engine 210 and one key dot product engine 212 for each element of the input sequence, e.g., each row of the input matrix X. The maximum supported length of the input sequence (e.g., the maximum quantity of rows of the digital input matrix X) is determined by the quantity of components of the attention engine 200. For simplicity of illustration, the attention engine 200 of FIG. 3 supports an input sequence with two elements. It should be appreciated that attention engine may support longer input sequences by having more of the subsequently described components, connected together as appropriate.

The digital-to-analog converter 202 receives the elements of the input sequence and converts them to analog signals. As previously noted, each element of the input sequence is a vector. Thus, the digital-to-analog converter 202 produces a vector x₁ of analog signals corresponding to the first element of the input sequence, and produces a vector x₂ of analog signals corresponding to the second element of the input sequence.

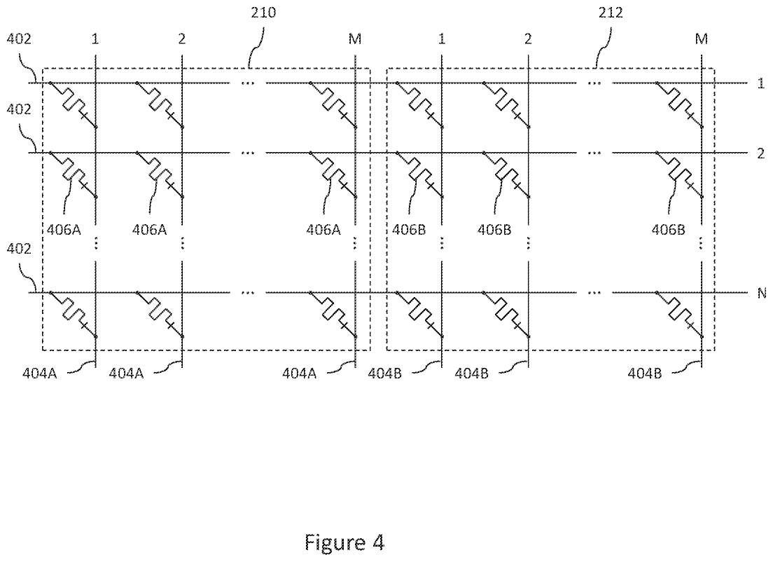

The dot product circuit 204 includes a plurality of crossbar arrays 400 coupled to the digital-to-analog converter 202. The crossbar arrays 400 include a first programmable crossbar array 400A (for the first element of the input sequence) and a second programmable crossbar array 400B (for the second element of the input sequence). The first programmable crossbar array 400A includes a first query dot product engine 210A and a first key dot product engine 212A. The second programmable crossbar array 400B includes a second query dot product engine 210B and a second key dot product engine 212B. A programmable crossbar array 400 is used to perform vector-matrix multiplication in the analog domain. Specifically, a programmable crossbar array 400 includes a number of programmable elements that function together within an array to perform a weighted sum of the outputs of a digital-to-analog converter 202. Turning briefly to FIG. 4, an example implementation of a programmable crossbar array 400 will be described.

FIG. 4 is a diagram of a programmable crossbar array 400 for an attention engine, according to some implementations. The programmable crossbar array 400 includes a plurality of input electrodes 402, a plurality of output electrodes 404 (including output electrodes 404A and output electrodes 404B), and plurality of programmable elements 406 (including programmable elements 406A and programmable elements 406B). The input electrodes 402 are arranged in rows, the output electrodes 404 are arranged in columns. Each programmable element 406 is positioned at a crosspoint or junction of an input electrode 402 and an output electrode 404. As input, the programmable crossbar array 400 takes a vector of analog signals (on the input electrodes 402).

The programmable elements 406 are circuit elements whose conductance is programmable. The programmable elements 406 are non-volatile analog devices, which may be adapted to store multiple bits of data. An example of a programmable element is a memristor, which includes a dielectric layer (e.g., an oxide layer) between two metal layers. When the programmable elements 406 are memristors, the programmable crossbar array 400 is a memristor array. Other examples of programmable elements include multi-bit flash memory cells, resistive random-access memory (ReRAM) cells, phase-change random-access memory (PCRAM) cells, magnetoresistive random-access memory (MRAM) cells, electrochemical random-access memory (ECRAM) cells, and the like.

The programmable crossbar array 400 may also include other peripheral circuitry (not separately illustrated) associated with the programmable crossbar array 400 when used as a storage device. For example, the programmable crossbar array 400 may include drivers connected to the input electrodes 402. An address decoder can be used to select an input electrode 402 and activate a driver corresponding to the selected input electrode 402. The driver for a selected input electrode 402 can drive a corresponding input electrode 402 with different voltages corresponding to a vector-matrix multiplication or the process of setting resistance values within the programmable elements 406 of the programmable crossbar array 400. Similar driver and decoder circuitry may be included for the output electrodes 404. Control circuitry may also be used to control application of voltages at the inputs of the programmable crossbar array 400. Input signals to the input electrodes 402 and the output electrodes 404 are analog signals. The peripheral circuitry above described can be fabricated using semiconductor processing techniques in the same integrated structure or semiconductor die as the programmable crossbar array 400.

The programmable crossbar array 400 includes a query dot product engine 210 and a key dot product engine 212. A first subset of the output electrodes 404A and a first subset of the programmable elements 406A are for the query dot product engine 210. A second subset of the output electrodes 404B and a second subset of the programmable elements 406B are for the key dot product engine 212. The programmable crossbar array 400 includes N input electrodes 402, M output electrodes 404A, and M output electrodes 404B. As described in further detail below, there are two main operations that occur during operation of the programmable crossbar array 400. The first operation is to program the programmable elements 406 in the programmable crossbar array 400 so as to map the mathematic values in an N×M matrix to the programmable elements 406A for the query dot product engine 210 and to map the mathematic values in another N×M matrix to the programmable elements 406B for the key dot product engine 212. The second operation is the dot product or vector-matrix multiplication operation. In this operation, input voltages are applied to the input electrodes 402 and output currents are obtained from the output electrodes 404, corresponding to the result of multiplying an N×1 vector with the N×M matrixes. The input voltages are below the threshold of the programming voltage of the programmable elements 406 so the resistance values of the programmable elements in the programmable crossbar array 400 are not changed during the vector-matrix multiplication operation.

A vector-matrix multiplication may be executed through the programmable crossbar array 400 by applying a set of voltages simultaneously along the input electrodes 402 of the programmable crossbar array 400 and collecting the currents through the output electrodes 404. The signal generated on an output electrode 404 is weighted by the corresponding conductance of the programmable elements 406 at the crosspoints of the output electrode 404 with the input electrodes 402, and that weighted summation is reflected in the current at the output electrode 404. Thus, the relationship between the voltages at the input electrodes 402 and the currents at the output electrodes 404A is represented by a vector-matrix multiplication of the input vector with the N×M matrix determined by the conductances of the programmable elements 406A for the query dot product engine 210. Similarly, the relationship between the voltages at the input electrodes 402 and the currents at the output electrodes 404B is represented by a vector-matrix multiplication of the input vector with the N×M matrix determined by the conductances of the programmable elements 406B for the key dot product engine 212.

The programmable crossbar array 400 may be programmed to store the N×M matrixes for the query dot product engine 210 and the key dot product engine 212 by modifying the conductances of the programmable elements 406. The conductances of the programmable elements 406 are values corresponding to the N×M matrixes. The conductances of the programmable elements 406 may be modified by imposing a voltage across the programmable elements 406 using the input electrode 402, the output electrodes 404, and corresponding voltage drivers. The voltage difference imposed across a programmable element 406 generally determines the resulting conductance of that programmable element 406. The programming process may be performed row-by-row.

Turning back to FIG. 3, the operation of the programmable crossbar arrays 400 will be described. A query weight matrix W^{Q} is stored in the programmable elements of the query dot product engines 210, which are used to calculate respective rows of a query matrix Q (see Equation (2)). A key weight matrix W^{K} is stored in the programmable elements of the key dot product engines 212, which are used to calculate respective rows of a key matrix K (see Equation (3)).

The inputs of the first programmable crossbar array 400A (e.g., the input electrodes 402) are connected to a subset of the outputs of the digital-to-analog converter 202. The first query dot product engine 210A and the first key dot product engine 212A, respectively, store values corresponding to a query weight matrix W^{Q} and a key weight matrix W^{K} in their programmable elements 406. The vector x₁ output from the digital-to-analog converter 202 is multiplied with the query weight matrix W^{Q} in the first query dot product engine 210A and with the key weight matrix W^{K} in the first key dot product engine 212A. The multiplication is performed in-memory by the first programmable crossbar array 400A. The first programmable crossbar array 400A outputs two vectors of analog signals: a vector q₁ of analog signals (on the output electrodes 404A) produced by multiplying the vector x₁ with the query weight matrix W^{Q} stored in the first query dot product engine 210A, and a vector k₁ of analog signals (on the output electrodes 404B) produced by multiplying the vector x₁ with the key weight matrix W^{K} stored in the first key dot product engine 212A. The vector q₁ corresponds to the first row of the query matrix Q (see Equation (2)), while the vector k₁ corresponds to the first row of the key matrix K (see Equation (3)). The vector q₁ and the vector k₁ have the same length. That length depends on the quantity of columns of, respectively the query weight matrix W^{Q} and the key weight matrix W^{K}.

The inputs of the second programmable crossbar array 400B (e.g., the input electrodes 402) are connected to a subset of the outputs of the digital-to-analog converter 202. The second query dot product engine 210B and the second key dot product engine 212B, respectively, store values corresponding to the query weight matrix W^{Q} and the key weight matrix W^{K} in their programmable elements 406. The vector x₂ output from the digital-to-analog converter 202 is multiplied with the query weight matrix W^{Q} in the second query dot product engine 210B and with the key weight matrix W^{K} in the second key dot product engine 212B. The multiplication is performed in-memory by the second programmable crossbar array 400B. The second programmable crossbar array 400B outputs two vectors of analog signals: a vector q₂ of analog signals (on the output electrodes 404A) produced by multiplying the vector x₂ with the query weight matrix W^{Q} stored in the second query dot product engine 210B, and a vector k₂ of analog signals (on the output electrodes 404B) produced by multiplying the vector x₂ with the key weight matrix W^{K} stored in the second key dot product engine 212B. The vector q₂ corresponds to the second row of the query matrix Q (see Equation (2)), while the vector k₂ corresponds to the second row of the key matrix K (see Equation (3)). The vector q₂ and the vector k₂ have the same length. That length depends on the quantity of columns of, respectively the query weight matrix W^{Q} and the key weight matrix W^{K}.

The same query weight matrix W^{Q} is stored in both the first query dot product engine 210A and the second query dot product engine 210B, while the same key weight matrix W^{K} is stored in both the first key dot product engine 212A and the second key dot product engine 212B. The multiplication of the first input sequence element with the query weight matrix W^{Q} and the key weight matrix W^{K} may thus happen simultaneously with the multiplication of the second input sequence element with the query weight matrix W^{Q} and the key weight matrix W^{K}. Each matrix multiplication is performed in the analog domain by a respective programmable crossbar array 400.

The multiplier circuit 206 includes a plurality of current multipliers 302 and a plurality of current summers 304. In an implementation, the multiplier circuit 206 is a CMOS circuit. Each current multiplier 302 is connected to an output of a query dot product engine 210 and to an output of a key dot product engine 212 (e.g., to two output electrodes 404). Specifically, different subsets of the current multipliers 302 are coupled to different subsets of the output electrodes 404 of the query dot product engines 210 and to different subsets of the output electrodes 404 of the key dot product engines 212. A current multiplier 302 may be based on bipolar junction transistors, MOSFET transistors, or the like. Examples of current multipliers include gilbert cells or the like. The outputs of groups of current multipliers 302 are connected to respective current summers 304, which sum the currents from the current multipliers 302. Each current summer 304 may be a common node to which multiple current multipliers 302 are connected.

A first subset of the current multipliers 302A receive the vector q₁ of analog signals and the vector k₁ of analog signals. Corresponding elements of the vector q₁ and the vector k₁ are fed into corresponding current multipliers 302A. Thus, the output of each current multiplier 302A is produced by multiplying a corresponding element of the vector q₁ with a corresponding element of the vector k₁. For example, the first element of the vector q₁ is multiplied with the first element of the vector k₁ using a first current multiplier 302A. The outputs of the current multipliers 302A are fed into a current summer 304A, which sums the currents from the current multipliers 302A. Thus, the output of the current summer 304A is a value corresponding to taking the dot product of the vector q₁ (e.g., the first row of the query matrix Q) and vector k₁ (e.g., the first row of the key matrix K).

A second subset of the current multipliers 302B receive the vector q₂ of analog signals and the vector k₁ of analog signals. Corresponding elements of the vector q₂ and the vector k₁ are fed into corresponding current multipliers 302B. Thus, the output of each current multiplier 302B is produced by multiplying a corresponding element of the vector q₂ with a corresponding element of the vector k₁. For example, the first element of the vector q₂ is multiplied with the first element of the vector k₁ using a first current multiplier 302B. The outputs of the current multipliers 302B are fed into a current summer 304B, which sums the currents from the current multipliers 302B. Thus, the output of the current summer 304B is a value corresponding to taking the dot product of the vector q₂ (e.g., the second row of the query matrix Q) and vector k₁ (e.g., the first row of the key matrix K).

A third subset of the current multipliers 302C receive the vector q₂ of analog signals and the vector k₂ of analog signals. Corresponding elements of the vector q₂ and the vector k₂ are fed into corresponding current multipliers 302C. Thus, the output of each current multiplier 302C is produced by multiplying a corresponding element of the vector q₂ with a corresponding element of the vector k₂. For example, the first element of the vector q₂ is multiplied with the first element of the vector k₂ using a first current multiplier 302C. The outputs of the current multipliers 302C are fed into a current summer 304C, which sums the currents from the current multipliers 302C. Thus, the output of the current summer 304C is a value corresponding to taking the dot product of the vector q₂ (e.g., the second row of the query matrix Q) and vector k₂ (e.g., the second row of the key matrix K).

A fourth subset of the current multipliers 302D receive the vector q₁ of analog signals and the vector k₂ of analog signals. Corresponding elements of the vector q₁ and the vector k₂ are fed into corresponding current multipliers 302D. Thus, the output of each current multiplier 302D is produced by multiplying a corresponding element of the vector q₁ with a corresponding element of the vector k₂. For example, the first element of the vector q₁ is multiplied with the first element of the vector k₂ using a first current multiplier 302D. The outputs of the current multipliers 302D are fed into a current summer 304D, which sums the currents from the current multipliers 302D. Thus, the output of the current summer 304D is a value corresponding to taking the dot product of the vector q₁ (e.g., the first row of the query matrix Q) and vector k₂ (e.g., the second row of the key matrix K).

The attention engine 200 further includes current-to-voltage converters 306. The current-to-voltage converters 306 are connected to the outputs of the multiplier circuit 206, e.g., to the current summers 304. Each current-to-voltage converter 306 is connected to a corresponding current summer 304, and converts the output of the current summer 304 to a corresponding voltage. The current-to-voltage converters 306 may be based on operational amplifiers. Examples of current-to-voltage converters include transimpedance amplifiers or the like. The outputs of the current-to-voltage converters 306 are coupled to the inputs of the analog-to-digital converter 208, which converts the analog signals from the current-to-voltage converters 306 to a digital output matrix QK^{T}. The outputs of the current summers 304A, 304B are converted by the current-to-voltage converters 306A, 306B to be the first row of the digital output matrix QK^{T}, while outputs of the current summers 304C, 304D are converted by the current-to-voltage converters 306C, 306D to be the second row of the digital output matrix QK^{T}.

The components of the attention engine 200 (described above) can be fabricated using semiconductor processing techniques in the same semiconductor die. For example, the dot product circuit 204 and the multiplier circuit 206 may be part of the same semiconductor die.

The attention engine 200 may be implemented in other manners than shown in FIG. 3. For example, a single query dot product engine may be utilized to store one copy of the query weight matrix W^{Q}, and each output of that query dot product engine may be connected to more than one current multiplier 302. Similarly, a single key dot product engine may be utilized to store one copy of the key weight matrix W^{K}, and each output of that key dot product engine may be connected to more than one current multiplier 302.

Other appropriate operations from Equation (1) may then be performed with the digital output matrix QK^{T} to compute the output sequence for the transformer. The attention engine 200 may include additional features. In some implementations, the attention engine 200 includes features used to perform additional matrix generation and multiplication operations.

FIG. 5 is a block diagram of some components of an attention engine 200, according to some implementations. This attention engine 200 includes the components shown in FIG. 2, and also includes components for performing additional operations in Equations (1)-(4). The attention engine 200 may be used to generate a value matrix V using Equation (4), and then calculate the attention matrix A using Equation (1). The attention engine 200 may further include a digital circuit 502, a digital-to-analog converter 504, a digital-to-analog converter 506, a dot product circuit 508, a multiplier circuit 510, and an analog-to-digital converter 512. FIG. 5 illustrates a flow of signals in the attention engine 200, wherein signals in the analog domain are shown with solid lines and signals in the digital domain are shown with dotted lines.

The digital circuit 502 is connected to the analog-to-digital converter 208. The digital circuit 502 receives the digital output matrix QK^{T} from the analog-to-digital converter 208. Next, the digital circuit 502 calculates SoftMax(QK^{T}/\sqrt{dₖ}) to obtain a SoftMax matrix. This calculation is performed in the digital domain. The digital circuit 502 may include an integrated circuit or the like.

The digital-to-analog converter 504 receives a digital SoftMax matrix that is the result of computing SoftMax(QK^{T}/\sqrt{dₖ}) from the digital circuit 502. The outcome of the SoftMax operation may then be converted back to the analog domain using the digital-to-analog converter 504. The output of the digital-to-analog converter 504 may be referred to as an analog SoftMax matrix.

The digital-to-analog converter 506 receives a digital input matrix X from the processor 102 (see FIG. 1) and converts the digital input matrix X to an analog input matrix X, in a similar manner as the digital-to-analog converter 202 previously described for FIG. 2. The digital-to-analog converter 506 may be similar to the digital-to-analog converter 202.

The dot product circuit 508 is coupled to the digital-to-analog converter 506. The dot product circuit 508 receives the analog input matrix X from the digital-to-analog converter 506 and generates an analog value matrix V. Each element of the analog value matrix V is an analog signal that corresponds to an element of a digital value matrix V (see Equation (4)). The dot product circuit 508 may include value dot product engines 214. The value dot product engines 214 may be implemented using programmable crossbar arrays 400, in a similar manner as previously described for FIG. 3.

Each of the value dot product engines 214 store values corresponding to a value weight matrix W^{V} (see Equation (4)). Specifically, each of the value dot product engines 214 is part of a different programmable crossbar array that stores the values corresponding to the value weight matrix W^{V}. The value dot product engines 214 are configured to generate the analog value matrix V by multiplying the analog input matrix X with the value weight matrix W^{V} stored in the value dot product engines 214.

The multiplier circuit 510 is coupled to the dot product circuit 508 and the digital-to-analog converter 504. The multiplier circuit 510 is configured to calculate an analog attention matrix A by multiplying the analog value matrix V (from the dot product circuit 508) with the analog SoftMax matrix (from the digital-to-analog converter 504). Thus, the multiplier circuit 510 performs, in the analog domain, an equivalent of a matrix multiplication in the digital domain. The multiplier circuit 510 may be implemented in a previous manner as previously described for FIG. 3. In an implementation, the multiplier circuit 510 is a CMOS circuit.

The analog-to-digital converter 512 is coupled to the multiplier circuit 510. The analog-to-digital converter 512 receives the analog attention matrix A and converts the analog attention matrix A to a digital attention matrix A. The digital attention matrix A may be output to the processor 102 (see FIG. 1). The digital attention matrix A represents the relationships of the elements of the input sequence to one another. This relationship may then be used by the processor 102 to generate a hidden state sequence for a transformer.

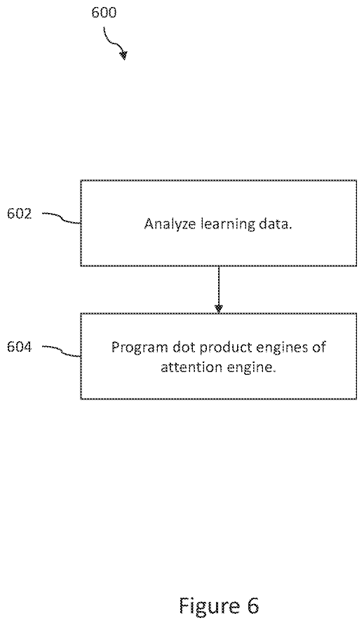

FIG. 6 is a diagram of an attention engine programming method 600, according to some implementations. The attention engine programming method 600 is performed by an inferencing engine during training of an LLM. Any processor may be used to execute the inferencing engine. For example, the attention engine programming method 600 may be performed by the processor 102 (see FIG. 1). In some implementations, an LLM is trained offline by another processor. The weights resulting from that training are then programmed into an attention engine 200 for use in a computing system 100 (see FIG. 1). The attention engine may be the attention engine 200 of FIG. 2 or the attention engine 200 FIG. 5.

The processor performs a step 602 of analyzing learning data. The learning data may be previously known data. The processor performs a step 604 of programming the dot product engines of an attention engine 200 based on the analysis of the learning data. Specifically, the query weight matrix W^{Q}, the key weight matrix W^{K}, and the value weight matrix W^{V} may be calculated by the processor and then stored in, respectively, the query dot product engines 210, the key dot product engines 212, and the value dot product engines 214. The dot product engines may be programmed in a similar manner as previously described, e.g., by imposing voltages across the programmable elements of the dot product engines to set the programmable elements' conductances.

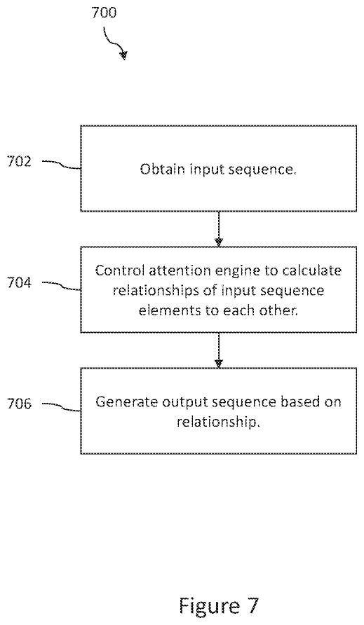

FIG. 7 is a diagram of a transformation method 700, according to some implementations. The transformation method 700 may be performed by the processor 102 (see FIG. 1) as part of processing a transformer of an LLM. For example, the transformation method 700 may be performed as part of a multi-head attention operation.

The processor 102 performs a step 702 of obtaining an input sequence. The input sequence may be received from a previous transformer. For example, the processor 102 may receive an input matrix X (previously described for Equations (1)-(4) and FIGS. 2, 3, and 4), where each row of the input matrix X is an element of the input sequence.

The processor 102 performs a step 704 of controlling the attention engine 200 to calculate the relationships of elements of the input sequence to each other. This calculation may include performing an attention operation (previously described for Equations (1)-(4)) on the input matrix X. The previously described attention engine 200 may be used by the processor 102 to calculate an attention matrix A (previously described for Equation (1)) for the input sequence. At least some of this calculation may be performed in the analog domain using the attention engine 200 of FIG. 2 or the attention engine 200 FIG. 5.

The processor 102 performs a step 706 of generating an output sequence based on the relationships of the elements of the input sequence to each other (e.g., the attention matrix A, see Equation (1)). The output sequence includes the input sequence plus additional information from the attention matrix A. The output sequence may be a hidden state sequence that is fed to a subsequent transformer or is used to predict the token for a segment.

Embodiments may achieve advantages. Performing matrix multiplication in the analog domain may be faster than performing it in the digital domain, particularly when the matrix generation and multiplication operations may be performed simultaneously using different programmable crossbar arrays and a multiplication circuit. Performing such operations may have O(n²) complexity in the digital domain (where n is the sequence length) but O(1) complexity in the analog domain. The reduced complexity may also allow the analog-domain computation to be made with reduced power relative to a digital-domain computation. Additionally, utilizing a CMOS-based multiplication circuit allows matrix multiplication to be performed without having to repeatedly reprogram the programmable crossbar arrays. The performance and reliability of the computing system may thus be improved.

The foregoing outlines features of several examples so that those skilled in the art may better understand the aspects of the present disclosure. Various modifications and combinations of the illustrative examples, as well as other examples, will be apparent to persons skilled in the art upon reference to the description. It is therefore intended that the appended claims encompass any such modifications.

What is claimed is:

1. A device comprising:
a first dot product circuit comprising a plurality of query dot product engines and a plurality of key dot product engines, each of the query dot product engines storing values corresponding to a query weight matrix, each of the key dot product engines storing values corresponding to a key weight matrix, the first dot product circuit configured to:
generate an analog query matrix by multiplying an analog input matrix with the query weight matrix stored in the query dot product engines; and
generate an analog key matrix by multiplying the analog input matrix with the key weight matrix stored in the key dot product engines; and
a first multiplier circuit coupled to the first dot product circuit, the first multiplier circuit configured to calculate an analog output matrix by multiplying the analog query matrix with a transpose of the analog key matrix.

2. The device of claim 1, further comprising:
a digital-to-analog converter coupled to the first dot product circuit, the digital-to-analog converter configured to receive a digital input matrix and convert the digital input matrix to the analog input matrix.

3. The device of claim 1, further comprising:
an analog-to-digital converter coupled to the first multiplier circuit, the analog-to-digital converter configured to receive the analog output matrix and to convert the analog output matrix to a digital output matrix.

4. The device of claim 1, further comprising:
a second dot product circuit comprising a plurality of value dot product engines, each of the value dot product engines storing values corresponding to a value weight matrix, the second dot product circuit configured to:
generate an analog value matrix by multiplying the analog input matrix with the value weight matrix stored in the value dot product engines; and
a second multiplier circuit coupled to the second dot product circuit, the first multiplier circuit configured to calculate an analog attention matrix by multiplying an analog SoftMax matrix with the analog value matrix.

5. The device of claim 4, further comprising:
a digital circuit configured to calculate a digital SoftMax matrix based on the analog output matrix; and
a digital-to-analog converter coupled to the digital circuit and the second multiplier circuit, the digital-to-analog converter configured to receive the digital SoftMax matrix and convert the digital SoftMax matrix to the analog SoftMax matrix.

6. The device of claim 4, further comprising:
an analog-to-digital converter coupled to the second multiplier circuit, the analog-to-digital converter configured to receive the analog attention matrix and to convert the analog attention matrix to a digital attention matrix.

7. The device of claim 1, wherein the first dot product circuit comprises a plurality of programmable crossbar arrays, and each of the programmable crossbar arrays comprises one of the query dot product engines and one of the key dot product engines.

8. The device of claim 7, wherein the programmable crossbar arrays are memristor arrays.

9. A device comprising:
a digital-to-analog converter;
a first programmable crossbar array comprising first input electrodes and first output electrodes, the first input electrodes coupled to a first subset of outputs of the digital-to-analog converter;
a second programmable crossbar array comprising second input electrodes and second output electrodes, the second input electrodes coupled to a second subset of the outputs of the digital-to-analog converter; and
current multipliers coupled to the first output electrodes and the second output electrodes.

10. The device of claim 9, wherein different subsets of the current multipliers are coupled to different subsets of the first output electrodes and to different subsets of the second output electrodes.

11. The device of claim 9, further comprising:
current summers coupled to the current multipliers;
current-to-voltage converters coupled to the current summers; and
an analog-to-digital converter coupled to the current-to-voltage converters.

12. The device of claim 11, wherein the current-to-voltage converters are transimpedance amplifiers and the current multipliers are gilbert cells.

13. The device of claim 9, wherein the first programmable crossbar array further comprises first programmable elements at first crosspoints of the first input electrodes and the first output electrodes, and the second programmable crossbar array further comprises second programmable elements at second crosspoints of the second input electrodes and the second output electrodes.

14. The device of claim 13, wherein the first programmable elements and the second programmable elements are memristors.

15. A method comprising:
obtaining an attention engine comprising a first dot product circuit and a multiplier circuit coupled to the first dot product circuit, the first dot product circuit comprising a plurality of query dot product engines and a plurality of key dot product engines;
analyzing learning data; and
programming the query dot product engines and the key dot product engines of the attention engine based on analysis of the learning data.

16. The method of claim 15, wherein the query dot product engines and the key dot product engines each comprise memristor arrays.

17. The method of claim 15, wherein the multiplier circuit comprises current multipliers.

18. The method of claim 15, wherein programming the query dot product engines and the key dot product engines comprises:
calculating a query weight matrix and a key weight matrix; and
storing the query weight matrix and the key weight matrix in, respectively, the query dot product engines and the key dot product engines.

19. The method of claim 18, wherein the query dot product engines and the key dot product engines each comprise programmable elements, and storing the query weight matrix and the key weight matrix comprises:
imposing voltages across the programmable elements.

20. The method of claim 15, wherein the attention engine further comprises a second dot product circuit, the second dot product circuit comprising a plurality of value dot product engines, and the method further comprises:
programming the value dot product engines of the attention engine based on analysis of the learning data.
